(19) United States
(12) Patent Application Publication
(10) Pub. No.: US 2018/0057350 A1
(43) Pub. Date: Mar. 1, 2018

(54) MICROMECHANICAL SYSTEM HAVING A STOP ELEMENT

(71) Applicant: Robert Bosch GmbH, Stuttgart (DE)

(72) Inventor: Juergen Mueller, Ofterdingen (DE)

(21) Appl. No.: 15/681,062

(22) Filed: Aug. 18, 2017

(30) Foreign Application Priority Data
Aug. 23, 2016 (DE) 102016215815.5

(51) Int. Cl. B81B 3/00

(52) U.S. Cl. CPC B81B 3/001; B81B 2203/0172; B81B 2203/0376

(57) ABSTRACT

A micromechanical system includes a substrate; a functional element that is mounted to as to allow movement in relation to the substrate; and an elastic stop element. The stop element has a first end that is attached to the substrate, and a second end that is configured to engage with the functional element when the functional element is deflected by a predefined amount from a neutral position. The stop element has an elastic configure in a first direction that coincides with a preferred direction of the functional element, and in a second direction that extends at a right angle to the first direction.

### RELATED APPLICATION INFORMATION

The present application claims priority to and the benefit of German patent application no. 10 2016 215 815.5, which was filed in Germany on Aug. 23, 2016, the disclosure which is incorporated herein by reference.

### FIELD OF THE INVENTION

The present invention relates to a micromechanical system. In particular, the present invention relates to a stop element for a mobile functional element of a micromechanical system.

### BACKGROUND INFORMATION

A micromechanical system includes a substrate and a functional element that is mounted so as to allow movement in relation to the substrate. Components of the micromechanical system (also known as MEMS—micro-electromechanical system or as micro-mechatronic system) usually have sizes in the range from 1 and 100 μm, and the micromechanical system has a size of approximately 20 μm to 1 mm in one dimension. Typical application areas for the micromechanical system include an acceleration sensor, a rate-of-rotation sensor, a pressure sensor, a sound sensor, a micromechanical replication of an apparatus such as a pump or a toothed wheel construction etc. By further miniaturization, a nano-technical system may be created from a micromechanical system, for which the correlations illustrated here apply accordingly.

The micromechanical system may respond in a sensitive manner when surfaces of its function structures come into contact with one another. In particular, the function structure may then adhere to another element so that the operativeness of the system may be restricted.

### SUMMARY OF THE INVENTION

One object on which the present invention is based consists of providing a micromechanical system that has an improved elastic stop element in order to better prevent an adhesion of the functional element to the stop element. The present invention achieves this objective by the subject matter described herein. The further descriptions herein disclose other specific embodiments.

A micromechanical system includes a substrate, a functional element that is mounted to as to allow movement in relation to the substrate, and an elastic stop element. The stop element has a first end that is fixed in place on the substrate, and a second end that is configured to engage with the functional element when the functional element is deflected by a predefined amount from a neutral position. The stop element has an elastic configuration in a first direction that coincides with a preferred direction of the functional element, and in a second direction that extends at a right angle to the first direction.

With the aid of the present invention it may be avoided that the functional element adheres to another element and fully or partially loses its mobility. The present invention may be used to effectively prevent an adhesion of the functional element to a section of the substrate, to a vertically oriented element rigidly connected to the substrate, or to some other mobile functional element. The adhesion of two deflectable diaphragms is also able to be prevented.

In order to avoid the adhesion, it is known to coat a surface (anti-stiction coating). However, the anti-stick effect of such coatings and the surface wetting are limited or may be interrupted by additional processes during the production of the micromechanical system. As an alternative, it was proposed to configure the element with a stiffness such that the probability of the critical surfaces coming into contact is drastically reduced statistically. However, this may lower the sensitivity of the micromechanical system. It has also been proposed to install elastic stops at critical strike points in the useful direction. When the corresponding surfaces make contact, the striking triggers an additional restoring force that may help to separate sticking surfaces again once they have made contact. However, a free travel of the functional element may be reduced as a result. In addition, in some micromechanical systems a two-dimensional movement of the functional element may occur so that the elastic stop is not only subjected to impact or pressure but also tangentially to friction. In particular, situations may arise in this context in which no or only light forces are acting along the preferred direction of the functional element yet friction that acts perpendicular thereto occurs nevertheless. The probability of sticking of the corresponding surfaces may be greatly increased under these circumstances.

According to the present invention, these disadvantages may be overcome by reliably preventing the adhesion of the functional element to another element by a two-dimensional operativeness of the stop element. Here, the present invention may be used in a micromechanical system, but given even greater miniaturization, also in a nano-technological system since the ratio of surface to volume of a system grows with increasing miniaturization, so that the control of surface effects becomes ever more important.

Frequently, the mobility of the functional element in relation to the micromechanical system may not be restricted to the preferred direction under all circumstances. The two-dimensionally elastic stop element is better able to absorb a two-dimensional movement of the functional element in the plane that is defined by the first and the second direction. Two random directions in space are combinable with each other for the movement. A lateral movement of the functional element in relation to the stop element, that is to say, sliding along or sliding off, is thereby able to be made less likely. Sticking between the functional element and the elastic stop element is better able to be prevented, and an adverse effect on the function of the micromechanical system caused by the sticking is better able to be avoided. The functional element featuring elasticity in two directions can be produced with the aid of known production technologies for micromechanical systems.

In a particularly specific embodiment, the second end of the stop element and a section of the functional element set up for the engagement are configured in such a way that a friction-locked engagement in both directions is possible. In a first variant, the second end of the stop element has a concave configuration for this purpose, and the section of the functional element configured for the engagement has an elongated form. In another variant, the second end of the stop element is elongated, and the section of the functional element configured for the engagement has a concave form.

The elongated element or the elongated section may be configured in the shape of a rod, in particular. The elongated element may permit free mobility of the functional element along both directions until it comes to engage with the concave element. The engagement with the concave element may take place in both directions. The concave section is able to be configured in C-form or U-form in the plane of the two directions, in particular.

In another specific embodiment, the elongated element has a convex end section. This makes it possible to more optimally specify a travel that the functional element is able to execute from the neutral position without coming to engage with the stop element. In particular, it may be provided that a radius of the convex element is smaller than a radius of the concave element. Movements of the functional element along only one direction may then be absorbed more optimally. An engagement region between the concave and the convex element may be smaller in size, thereby reducing the risk of sticking of the elements.

The stop element is able to be configured in various ways in order to ensure the elasticity along the two directions. In a specific embodiment, the stop element includes a first flexural member for producing the elastic deformability in the first direction; it also includes a second flexural member, which is fixed in place on the first flexural member, for producing the elastic deformability in the second direction. Each flexural member may be configured as a bending beam or a diaphragm, for example. In this way, the elasticity of the stop element may be better defined in both directions independently of each other.

In another specific embodiment, two second flexural members are situated parallel to each other and are connected to each other in their external regions. Here, forces may be introduced and/or dissipated at the internal regions of the flexural members. Such a system is known as a frame structure or an elastic frame.

The preferred direction of the functional element may run parallel to a surface of the substrate. A system of this type is common especially in the case of acceleration or rate-of-rotation sensors, and it may permit a simplified development of the described stop element.

In different specific embodiments, the two directions may be selected as desired; as a rule, a planar surface of the substrate is used as the basis for the orientation. However, it is also possible that the elastic element is elastic in a third direction that extends at a right angle to the two other directions. This makes it possible to absorb or buffer stresses in all three directions in space.

It may be provided here that a contact structure of the type of a cup-and-saucer connection is configured between the functional element and the second end of the stop element. This corresponds to a three-dimensional expansion of the afore-described specific embodiment with a concave and an elongated section.

The present invention will now be described in greater detail with reference to the attached figures.

### BRIEF DESCRIPTION OF THE FIGURES

FIG. 1 shows a micromechanical system.

FIG. 2 shows a part of the micromechanical system from FIG. 1 in an enlarged view.

FIG. 3 shows a stop element on a micromechanical system.

### DETAILED DESCRIPTION

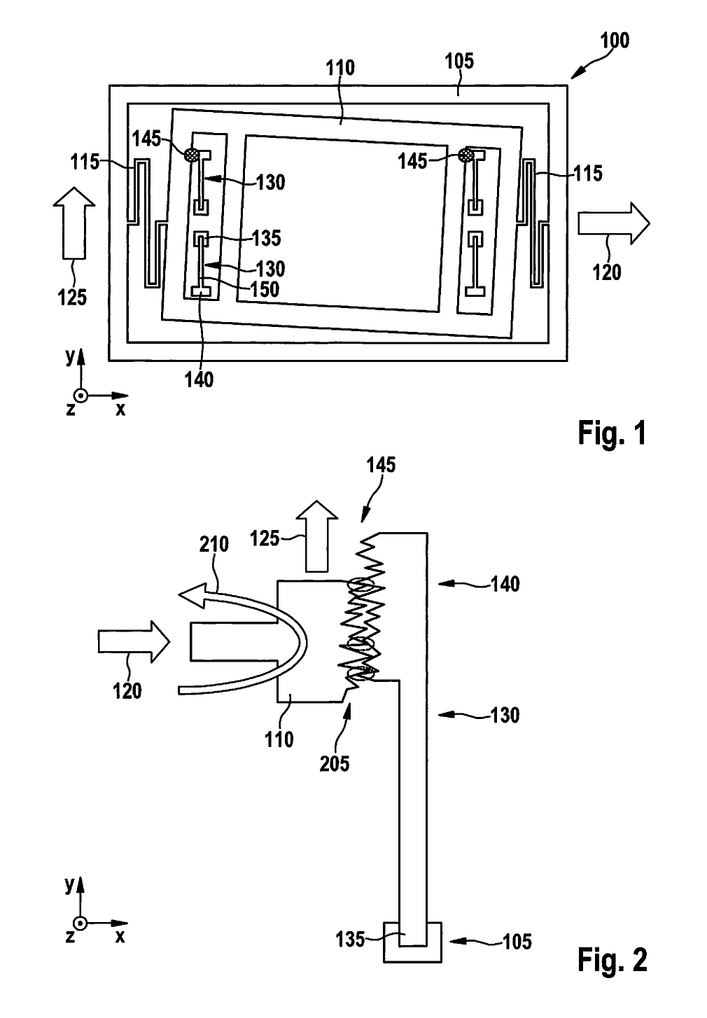

FIG. 1 shows a micromechanical system 100 having a substrate 105 and a functional element 110. For instance, micromechanical system 100 may include a sensor, in particular an acceleration sensor or a rate-of-rotation sensor. For easier referencing, a coordinate system having a first direction (X), a second direction (Y) and a third direction (Z), has been illustrated in FIG. 1 and the following figures in each case. Directions X and Y define a plane in which a surface of substrate 105 may extend. However, it should be noted that all other combinations and orientations of a Cartesian coordinate system are possible as specific embodiments. Micromechanical system 100 is normally able to be produced using means from the semiconductor technology and may include different semiconductor materials. Substrate 105 may serve as a solid assembly frame and may include silicon, for instance. Other elements of system 100 may include silicon dioxide or, as a conductive layer, a metallization.

Functional element 110 may be kept mobile with respect to substrate 105, for instance with the aid of an elastic suspension or an elastic diaphragm 115. In particular, functional element 110 is able to move along a preferred direction 120, which coincides with first direction X. However, mobility in a transverse direction 125, which extends at a right angle to preferred direction 120, is not always able to be prevented completely. In the specific embodiment illustrated, transverse direction 125 coincides with second direction Y.

If no further forces are acting on functional element 110, then it assumes a predefined neutral position. Exposed to external influences, functional element 110 may move from the neutral position by a predefined amount. In order to limit such a movement, at least one stop element 130 is provided, which includes a first end 135 and second end 140. First end 135 is attached to substrate 105, and second end 140 is configured to engage with functional element 110 when functional element 110 is deflected from the neutral position by a predefined amount. In the illustrated specific embodiment, functional element 110 is deflected in such a way that an engagement 145 is present at two of the four stop elements 130 illustrated.

Between first end 135 and second end 140, stop element 130 includes a flexural member 150 which permits a movement of second end 140 relative to first end 135 at least along first direction 120.

FIG. 2 shows a region of an engagement 145 between functional element 110 and stop element 130 of micromechanical system 100 of FIG. 1. The illustrated part essentially corresponds to stop element 130 shown in the upper left area in FIG. 1.

Functional element 110 encompasses a section 205, which is configured for an engagement with second end 140 of stop element 130. Surfaces of section 205 of functional element 110 and of second end 140 of stop element 130 are illustrated with a greater roughness. When functional element 110 executes a combined movement 210, which is composed of movements in first direction 120 and second direction 125, then a lateral, chafing or scuffing movement may result between section 205 and second end 140. Especially in cases where a force component along first direction 120 is low, various surface structures in an atomic or molecular scale may successively make contact with one another between section 205 and second end 140 during the sliding process. This contact may take place in such a way that continuously increasing sticking is produced because increasingly more and increasingly better adhering surface segments make contact with one another in the lateral movement. It is statistically improbable that a very sticky or meshed surface condition shifts to a less sticky condition during the described process, especially because the kinetic energy of functional element 110 diminishes during the lateral movement.

As a consequence, stop element 130 may cause a critical, adhesion-producing effect due to the sliding movement along second direction 125, and the desired force-reaction of stop element 130 in opposition to the sticking may be very heavily reduced. This may particularly stem from the fact that the detachment force is acting in a perpendicular direction with respect to the adhering surface segments. In the type of stop or movement described, elastic stop element 130 may largely have no effect.

The risk of sticking in a lateral movement along second direction 125 may be considerable in particular when one of the surfaces of section 205 or of second end 140 of stop element 130 is rough not only in the atomic range but also includes larger structures such as grooves, blades or roughness in the sub-micrometer to micrometer range. This characteristic is frequently encountered in MEMS and nano-structures.

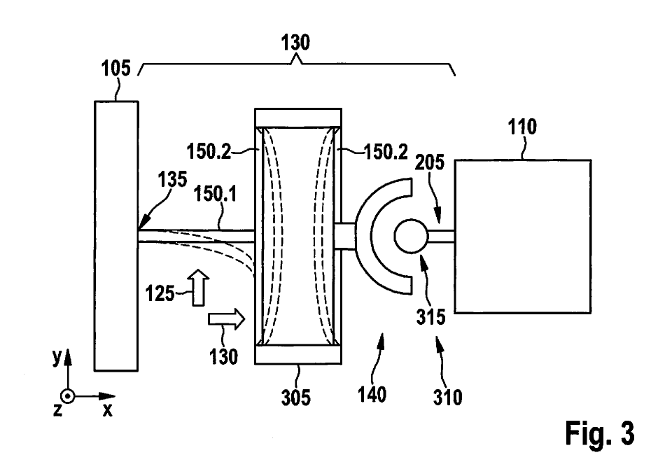

FIG. 3 shows a specific embodiment of a stop element 130 in a micromechanical system 100 like the one shown in FIG. 1. Stop element 130 is configured to exhibit an elastic behavior both along first direction 120 and along second direction 125. Toward this end, flexural member 150 may be configured in such a way that it is elastic along both directions 120, 125. In the specific embodiment shown here, a first flexural member 150.1 and a second flexural member 150.2 are provided in cascading form. Second flexural member 150.2 is fixed in place on first flexural member 150.1 so that both flexural members 150.1, 150.2 lie mechanically in series between first end 135 and second end 140. One of flexural members 150.1, 150.2 may also be provided with a frame structure, as shown in FIG. 3 by way of example, with respect to second flexural member 150.2. For this purpose, two second flexural members 150.2 are disposed in parallel with each other, their external regions being connected to each other, which may be with the aid of a frame element 305. Frame element 305 may be elastically deformable in a plurality of dimensions. The introduction or dissipation of forces preferably takes place in the interior region of second flexural member 150.2.

Furthermore, it may be provided that a contact structure 310 is configured between functional element 110 and stop element 130 for the engagement. This is done in that second end 140 of stop element 130 and section 205 of functional element 110 configured for an engagement with second end 140 are given a mutually corresponding configuration. For one, this allows for free mobility of functional element 110 with respect to substrate 105 along both directions 120, 125 as long as the deflection of functional element 110 from the neutral position does not exceed a predefined amount. For another, it allows for the realization of a reliable frictional connection along both directions 120, 125 when the predefined amount is exceeded. Toward this end, it may be provided that second end 140 is configured in concave form and section 205 is configured in elongated form, i.e. is oblong, in particular. A reversed specific embodiment, in which second end 140 is elongated and section 205 is concave, is possible as well.

In the specific development illustrated, second end 140 is configured in a C-shape or a U-shape in the plane of directions 120, 125, in particular. If a free distance between section 205 and second end 140 along the two directions 120, 125 is to differ, then the concave form of second end 140 is able to be modified accordingly. In other words, the U-shape may have a correspondingly flatter or narrower development.

In addition, it may be provided that section 205 includes a convex end section 315. A radius of curvature of end section 315 may be smaller than a radius of curvature of concave second end 140.

In another specific embodiment, stop element 130 may additionally have an elastic configuration along third direction (Z). For this purpose, for instance, first flexural member 150.1 may be elastic also along the third direction, or a dedicated third flexural member may be provided which is connected in series with the other two and ensures the elasticity in the Z-direction. Contact structure 310 may easily be expanded to the third direction in that the surfaces, provided for the mutual engagement, of second end 140 of stop element 130 and of section 205 of functional element 110 are provided essentially in axial symmetry with respect to second direction 125. Concave second end 140 is then concave also in the third dimension, in the manner of a dish or bowl. Convex end section 315 of section 205 may be configured in a three-dimensionally convex form, in the form of a spherical segment.

What is claimed is:

1. A micromechanical system, comprising:
a substrate;
a functional element mounted so as to allow movement in relation to the substrate;
an elastic stop element having a first end that is attached to the substrate, and a second end configured to engage with the functional element when the functional element is deflected by a predefined amount from a neutral position;
wherein the elastic stop element is elastic in a first direction that coincides with a preferred direction of the functional element, and
wherein the elastic stop element has an elastic configuration in a second direction that extends at a right angle to the first direction.

2. The system of claim 1, wherein the second end of the stop element has a concave configuration and a section of the functional element configured for the engagement has an elongated configuration.

3. The system of claim 1, wherein the second end of the stop element is elongated, and a section of the functional element configured for the engagement is concave.

4. The system of claim 2, wherein the elongated element has a convex end section.

5. The system of claim 4, wherein a radius of the convex element is smaller than a radius of the concave element.

6. The system of claim 1, wherein the stop element includes a first flexural member for producing the elastic deformability in the first direction, and a second flexural member, mounted on the first flexural member, for producing the elastic deformability in the second direction.

7. The system of claim 6, wherein two second flexural members are disposed parallel to each other and are connected to each other in their external regions.

8. The system of claim 1, wherein the preferred direction extends parallel to a surface of the substrate.

9. The system of claim 1, wherein the elastic element is elastic in a third direction that extends at a right angle to the two other directions.

10. The system of claim 9, wherein a contact structure of the type of a cup-and-saucer connection is configured between the functional element and the second end of the stop element.
